(19) United States
(12) Patent Application Publication
(10) Pub. No.: US 2020/0227343 A1
(43) Pub. Date: Jul. 16, 2020

(54) SEMICONDUCTOR DEVICE PACKAGE

(71) Applicant: CHANG WAH TECHNOLOGY CO., LTD., Kaohsiung City (TW)

(72) Inventor: Chia-Neng HUANG, Kaohsiung City (TW)

(73) Assignee: CHANG WAH TECHNOLOGY CO., LTD., Kaohsiung City (TW)

(21) Appl. No.: 16/245,428

(22) Filed: Jan. 11, 2019

(51) Int. Cl. H01L 23/495; H01L 23/31; H01L 33/52

(52) U.S. Cl. CPC H01L 23/495; H01L 33/52; H01L 23/3114

(57) ABSTRACT

A semiconductor device package includes a metallic leadframe unit including a supporting base and a plurality of leads, a molding layer the leadframe unit, a plurality of solder grooves, and a semiconductor device disposed on the supporting base. The solder grooves are located under the leads such that lead bottom surfaces are uncovered by the molding layer. Each of the solder grooves has an end opening at a molding-layer side surface. The molding-layer side surface has a plurality of surface sections connected with each other, and any two adjacent ones of the surface sections define a joint portion. The leads are correspondingly exposed from the surface sections. The metallic leadframe unit is unexposed from the joint portions.

### FIELD

The disclosure relates to a semiconductor device package, and more particularly to a semiconductor device package including a plurality of solder grooves for inspecting solder visually.

### BACKGROUND

Quad flat no-lead (QFN) lead frames have been popularly used for producing semiconductor device packages with increased packaging density and decreased packaging size. Each of the semiconductor device packages is formed with a plurality of solder joints at the bottom thereof. While the solder joints are adapted for connecting external components, quality of the solder joints and completeness of electrical connection between the solder joints and the external components cannot be inspected simply by visual inspection. In addition, due to process limitations, a semiconductor device assembly including a plurality of the semiconductor device packages is generally formed with a mass of metal connection portions among the semiconductor device packages. When the semiconductor device assembly is subjected to singulation for separating the semiconductor device packages, a mass of cutting operations are needed, which results in a cutter wear problem.

### SUMMARY

Therefore, an object of the disclosure is to provide a semiconductor device package that can alleviate at least one of the drawbacks of the prior art.

According to the disclosure, a semiconductor device package includes a metallic leadframe unit, a molding layer, a plurality of solder grooves, and a semiconductor device.

The metallic leadframe unit includes a supporting base and a plurality of spaced-apart leads each extending from the supporting base. The supporting base has a supporting-base top surface and a supporting-base bottom surface opposite to the supporting-base top surface. Each of the leads has a lead bottom surface non-coplanar with the supporting-base bottom surface.

The molding layer surrounds the supporting base and the leads of the metallic leadframe unit. The molding layer has a molding-layer top surface, a molding-layer bottom surface opposite to the molding-layer top surface and a molding-layer side surface connected between the molding-layer top surface and the molding-layer bottom surface. The supporting-base top surface is exposed from and coplanar with the molding-layer top surface. The supporting-base bottom surface is exposed from and coplanar with the molding-layer bottom surface.

Each of the solder grooves is indented from the molding-layer bottom surface and is located under a respective one of the leads such that the lead bottom surfaces of the leads are uncovered by the molding layer. Each of the solder grooves has a first end meeting the supporting base and a second end opposite to the first end and opening at the molding-layer side surface.

The semiconductor device is disposed on the supporting-base top surface of the supporting base of the metallic leadframe unit.

The molding-layer side surface of the molding layer has a plurality of surface sections connected with each other. Any two adjacent ones of the surface sections define a joint portion therebetween. Each of the leads is exposed from a corresponding one of the surface sections of the molding-layer side surface. The metallic leadframe unit is unexposed from the joint portions of the molding-layer side surface.

### BRIEF DESCRIPTION OF THE DRAWINGS

Other features and advantages of the disclosure will become apparent in the following detailed description of the embodiments with reference to the accompanying drawings, of which:

FIG. 1 is a top perspective view illustrating a first embodiment of a semiconductor device package according to the disclosure;

FIG. 2 is a bottom perspective view illustrating the first embodiment;

FIG. 3 is a cross-sectional schematic view taken along line III-III of FIG. 1;

FIG. 4 is a perspective view containing parts (a) to (e) to illustrate consecutive steps of a method of making the first embodiment of the semiconductor device package;

FIG. 5 is a cross-sectional schematic view taken along line V-V of a structure formed in part (e) of FIG. 4;

FIG. 6 is a top perspective view illustrating a second embodiment of the semiconductor device package according to the disclosure;

FIG. 7 a cross-sectional schematic view taken along line VII-VII of FIG. 6;

FIG. 8 is a cross-sectional schematic view illustrating the first embodiment further including a bottom electro-plating layer;

FIG. 9 is a cross-sectional schematic view illustrating the first embodiment of FIG. 8 further including a top electro-plating layer;

FIG. 10 is a cross-sectional schematic view illustrating the first embodiment of FIG. 8 further including a groove electro-plating layer; and

FIG. 11 is a cross-sectional schematic view illustrating the first embodiment of FIG. 9 further including a groove electro-plating layer.

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

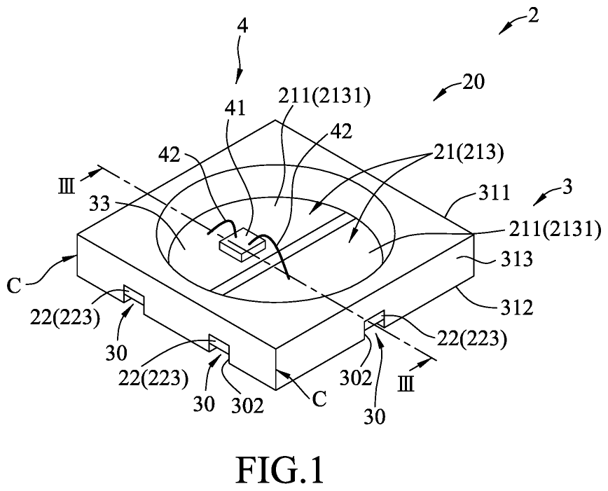

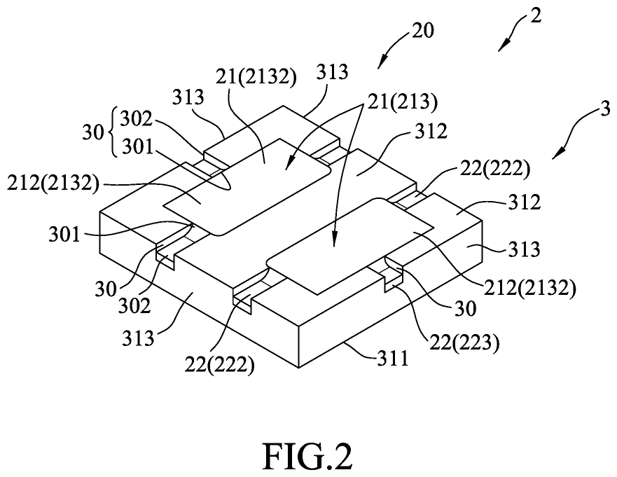

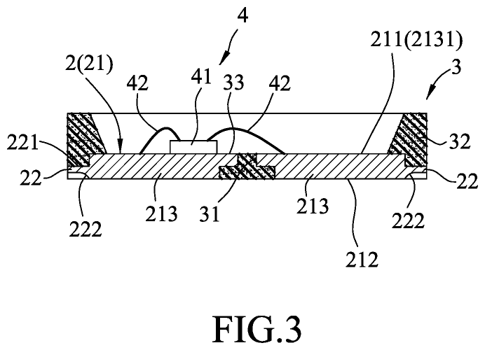

Referring to FIGS. 1 to 3, a first embodiment of a semiconductor device package 2 includes a metallic leadframe unit 20, a molding layer 31, an upper molding layer 32, a plurality of solder grooves 30, and a semiconductor device 4.

The metallic leadframe unit 20 may be made from a metallic material selected from the group consisting of copper, a copper-based alloy, an iron-nickel alloy, and combinations thereof. The metallic leadframe unit 20 includes a supporting base 21 and a plurality of spaced-apart leads 22 each extending from the supporting base 21. The supporting base 21 has a supporting-base top surface 211 and a supporting-base bottom surface 212 opposite to the supporting-base top surface 211. Each of the leads 22 has a lead top surface 221 and a lead bottom surface 222 that is opposite to the lead top surface 221 and that is non-coplanar with the supporting-base bottom surface 212. The lead top surface 221 may be indented from the supporting-base top surface 211 of the supporting base 21.

To be specific, the supporting base 21 of the metallic leadframe unit 20 includes at least two contact electrodes 213 that are spaced apart from each other. Each of the leads 22 extends from a corresponding one of the contact electrodes 213. The contact electrodes 213 respectively have top ends 2131 constituting the supporting-base top surface 211 and bottom ends 2132 constituting the supporting-base bottom surface 212. In the embodiment, the top end 2131 of at least one of the contact electrodes 213 is configured for disposing the semiconductor device 4. It is noted that a number of the contact electrodes 213 may be more than two and may be determined based on actual use, such as polarity and quantity of the semiconductor device 4. In this embodiment, the metallic leadframe unit 20 includes two of the contact electrodes 213.

The molding layer 31 surrounds the supporting base 21 and the leads 22 of the metallic leadframe unit 20. The molding layer 31 has a molding-layer top surface 311, a molding-layer bottom surface 312 opposite to the molding-layer top surface 311, and a molding-layer side surface 313 connected between the molding-layer top surface 311 and the molding-layer bottom surface 312. The supporting-base top surface 211 is exposed from and coplanar with the molding-layer top surface 311. The supporting-base bottom surface 212 is exposed from and coplanar with the molding-layer bottom surface 312. The molding layer 31 in combination with the metallic leadframe unit 20 may exhibit a hexahedral shape, such as a cube or a rectangular cuboid.

In this embodiment, the molding layer 31 is filled in a gap between the contact electrodes 213 and surrounds the contact electrodes 213. The molding layer 31 is directly molded over the metallic leadframe unit 20. The lead top surfaces 221 of the leads 22 are covered by the molding layer 31. The lead bottom surfaces 222 of the leads 22 are indented inward from the supporting-base bottom surface 212 of the supporting base 21 so as to be non-coplanar therewith. In other words, each of the leads 22 has a thickness less than that of the supporting base 21.

The solder grooves 30 can serve as solder seen terminals (SSTs). Each of the solder grooves 30 is indented from the molding-layer bottom surface 312 and located under a respective one of the leads 22 such that the lead bottom surfaces 222 of the leads 22 are uncovered by the molding layer 31. Each of the solder grooves 30 has a first end 301 meeting the supporting base 21 and a second end 302 opposite to the first end 301 and opening at the molding-layer side surface 313.

The lead bottom surface 222 of each of the leads 22 faces the respective one of the solder grooves 30 and is exposed from the molding layer 31 within the respective solder groove 30. In this embodiment, the exposed lead bottom surface 222 of each of the leads 22 is inward concaved relative to the molding-layer side surfaces 31. Alternatively, the exposed lead bottom surface 221 of each of the leads 22 may be inclined. The inwardly concaved or inclined configuration of the lead bottom surfaces 222 of the leads 22 contributes to directing flow of a liquid or colloid material, such as a conductive adhesive or solder, to the bottom ends 2132 of the contact electrodes 213.

Each of the leads 22 further has a lead side surface 223 extending upwardly from the lead bottom surface 221. The lead side surfaces 223 of the leads 22 may be coplanar with the molding-layer side surface 313 of the molding layer 31 or may be indented from the molding-layer side surface 313 so as to be non-coplanar therewith.

In this embodiment, the molding-layer side surface 313 of the molding layer 31 has a plurality of surface sections connected with each other. Any two adjacent ones of the surface sections define a joint portion (C) therebetween. Each of the leads 22 is exposed from a corresponding one of the surface sections of the molding-layer side surface 313. The metallic leadframe unit 20 is unexposed from the joint portions (C) of the molding-layer side surface 313. Particularly, based on the structural design of the disclosure, even if the semiconductor device package 2 includes any additional metallic portions connected to or separated from the supporting base 21 or the leads 22, such as residual leadframe parts after cutting operations or additional leads, these additional metallic portions are unexposed from and covered by the joint portions (C) of the molding-layer side surface 313.

The upper molding layer 32 is disposed on the supporting-base top surface 211 and partially covers the top end 2131 of each of the contact electrodes 213 to form a mounting area 33 that is exposed from the upper molding layer 32. In this embodiment, The upper molding layer 32 is directly molded over the molding layer 31.

The semiconductor device 4 is disposed on the supporting-base top surface 211 of the supporting base 21 of the metallic leadframe unit 20. To be specific, the semiconductor device 4 is disposed in the mounting area 33. The semiconductor device 4 includes at least one semiconductor chip 41 disposed on the top end 2131 of one of the contact electrodes 213 in the mounting area 33 and a plurality of wires 42. The semiconductor chip 41 is electrically connected to the other one of the contact electrodes 213 through at least one of the wires 42. In this embodiment, a number of the at least one semiconductor chip 41 is exemplified to be one. The semiconductor chip 41 may be a conventional chip for controlling a power source or processing analog signals, or a light-emitting chip. The light-emitting chip is unlimitedly to be a light emitting diode or a laser diode, etc. The molding layer 31 and the upper molding layer 32 may be made from a light-transmitting material or an opaque material.

In this embodiment, the semiconductor device 4 is a light-emitting device including at least one light-emitting chip, and the upper molding layer 32 is exemplified to be light reflective. Hence, multiple reflections of light emitted from the light-emitting device 4 can be generated in the upper molding layer 32, and thus light extraction efficiency of the light-emitting device 4 can be enhanced. An encapsulant (not shown) may be subsequently disposed in the mounting area 33 so as to be flush with the upper molding layer 32 and so as to encapsulate the semiconductor device 4. The encapsulant may be made from a transparent encapsulating polymeric material encapsulating material or an encapsulating polymeric material containing a fluorescent material.

In this embodiment, the solder grooves 30 respectively formed under the leads 22 expose the lead-bottom surfaces 222 of the leads 22 from the molding layer 31 and keep the metallic leadframe unit 20 unexposed from the joint portions (C) of the molding-layer side surface 313.

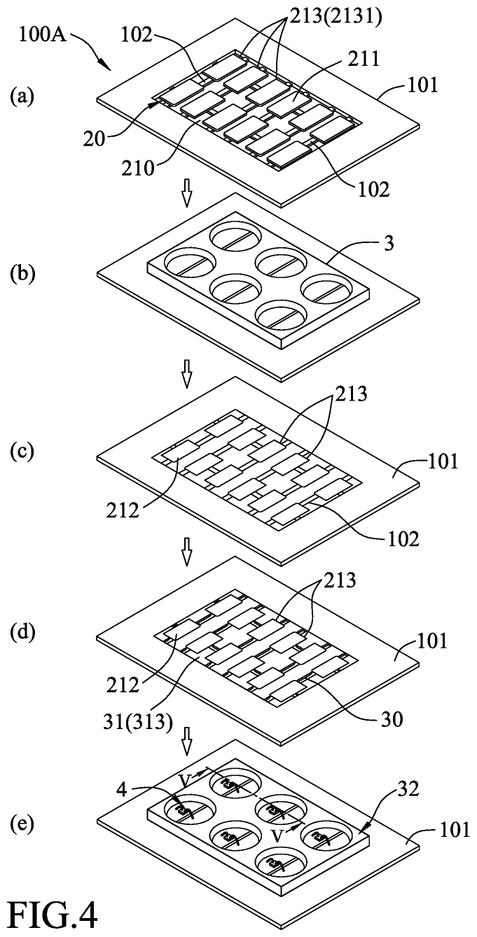

Referring to FIG. 4, a method of making the first embodiment of the semiconductor device package 2 is illustrated below.

First, an electrically conductive substrate, which may be made of a metallic material selected from the group consisting of copper, a copper-based alloy, an iron-nickel alloy, and combinations thereof, is etched to form a leadframe semi-product 100A (as shown in a part (a) of FIG. 4).

The leadframe semi-product 100A includes a framing portion 101, a plurality of spaced-apart connecting portions 102, and a plurality of the metallic leadframe units 20 which are surrounded by the framing portion 101 and each of which includes the two spaced-apart contact electrodes 213. The contact electrodes 213 are arranged in an array, and each of the contact electrodes 213 has the top end 2131 and the bottom end 2132. The connecting portions 102 are provided for connecting the metallic leadframe units 20 with each other and for connecting the metallic leadframe units 20 and the framing portion 101. In other words, each of the contact electrodes 213 of each of the metallic leadframe units 20 is connected to an adjacent one of the contact electrodes 213 of an adjacent one of the metallic leadframe units 20 through one of the connecting portions 102, and is connected to the framing portion 101 through at least one of the connecting portions 102. Hence, the framing portion 101, the contact electrodes 213 and the connecting portions 102 of the leadframe semi-product 100A are integrally formed.

Thereafter, the leadframe semi-product 100A is disposed in a mold (not shown), and an encapsulating polymeric material, which may be made from epoxy or silicon resin, is filled in a space 210 among the contact electrodes 213 and the framing portion 101, and covers the connecting portions 102 and a part of the top ends 2131 of the contact electrodes 213, followed by curing of the encapsulating polymeric material to form the molding layer 31 and the upper molding layer 32. Parts (b) and (C) of FIG. 4 are respectively top and bottom views of the leadframe semi-product 100A formed with the molding layer 31.

Each of the connecting portions 102 is then partially removed from a bottom surface of the leadframe semi-product 100A by the etching techniques so as to form the leads 22 and the solder grooves 30. The solder grooves 30 are indented from the molding-layer bottom surface 313 (as shown in part (d) of FIG. 4) and are respectively located under the leads 22 in the configuration of the leadframe semi-product 100A shown in part (b) of FIG. 4. Consequently, the leads 22 not only connect two adjacent contact electrodes 213 of any two adjacent ones of the metallic leadframe units 20 but connect the contact electrodes 213 of the metallic leadframe units 20 and the framing portion 101. It is noted that the etching process is controllable for making the lead side surface 223 of each of the leads 22 to be coplanar with the molding-layer side surface 313 or to be indented from the molding-layer side surface 313 so as to be non-coplanar therewith.

Thereafter, the semiconductor chip 41 of the semiconductor device 4 of each of the metallic leadframe units 20 is disposed on the one of the contact electrodes 213, and then the wire 42 is connected between the semiconductor chip 41 and the other one of the contact electrodes 213 (see part (e) of FIG. 4).

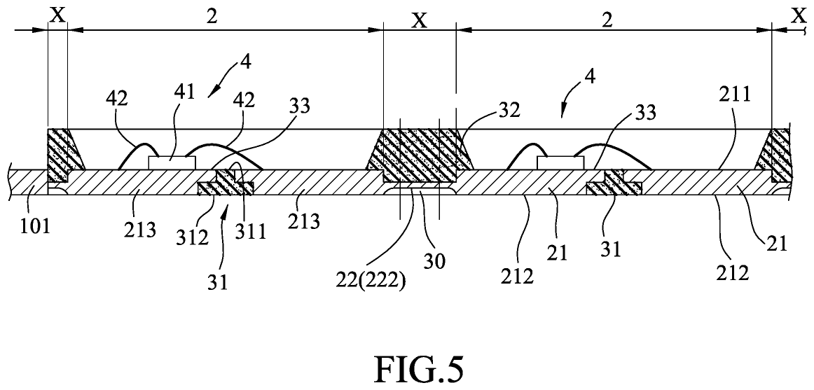

Further referring to FIG. 5, after the encapsulant flush with the upper molding layer 32 (not shown) is disposed in the mounting areas 33, a plurality of the semiconductor device packages 2 (only two are shown) are singularized by dicing along a scribe line (not shown) defined in dicing regions (X) formed in the molding layer 31.

Since each of the leads 22 is relatively thin in thickness and is small in area size, the cutting member will cut relatively little bits of the metallic leadframe unit 20 when dicing along the dicing regions (X). Therefore, the cutting wear caused by singularization of the semiconductor device packages 2 is reduced.

Alternatively, the molding layer 31 and the upper molding layer 32 may be formed sequentially using different molds. The molding layer 31 extends around the contact electrodes 213, and has the molding-layer bottom surface 311 coplanar with the bottom ends 2132 of the contact electrodes 213 and the molding-layer top surface 312 coplanar with the top ends 2131 of the contact electrodes 213. The upper molding layer 32 is formed on the molding layer 31 and partially covers the top ends 2131 of the contact electrodes 213. When the molding layer 31 and the upper molding layer 32 are not formed at the same time, the molding layer 31 and the upper molding layer 32 may be optionally made from identical or different encapsulating polymeric materials (e.g. epoxy resin or silicon, etc.).

When the semiconductor chip 41 is the light-emitting chip, light reflecting particles may be optionally included in the polymeric encapsulating materials for forming the upper molding layer 32, so that the upper molding layer 32 is light reflective. Therefore, light extraction efficiency of the light emitting chip 41 can be enhanced. Since the molds and the light reflecting particles per se are not the essential features of the disclosure, and are well known to those skilled in the art, further details thereof are not provided herein for the sake of brevity.

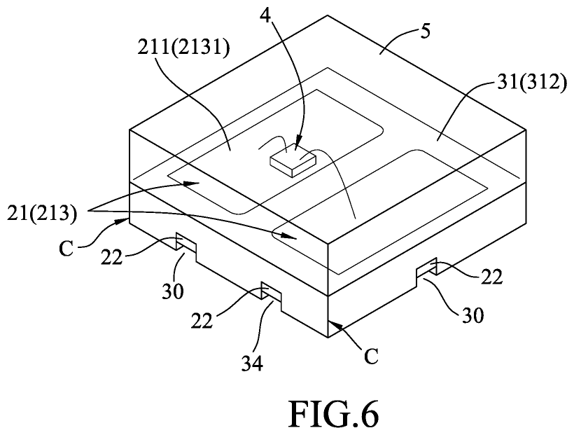

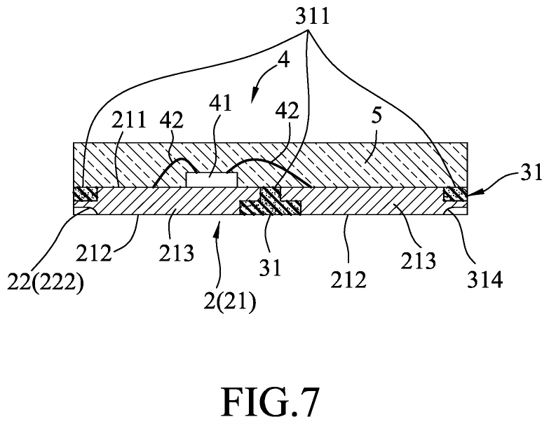

Referring to FIGS. 6 and 7, the second embodiment of the semiconductor device package 2 according to the disclosure is illustrated. The semiconductor device package 2 has a structure similar to that of the first embodiment and is free of the upper molding layer 32. In this embodiment, the semiconductor device package 2 further includes an encapsulant 5 formed on the molding layer 31, the supporting base 21 and encapsulating the semiconductor device 4.

More specifically, in this embodiment, the molding-layer top surface 311 is coplanar with the top ends 2131 of the contact electrodes 213, and the molding-layer bottom surface 312 is coplanar with the bottom ends 2132 of the contact electrodes 213. Thus, the metallic leadframe unit 20 in cooperation with the molding layer 31 to form a plate-shaped configuration. Similar to the first embodiment, the semiconductor chip 41 of the semiconductor device 4 is disposed on the top end 2131 of one of the contact electrodes 213 and is electrically connected to the other one of the contact electrodes 213 through at least one of the wires 42. The encapsulant 5 is directly disposed on the molding-layer top surface 311 of the molding layer 31 and the supporting-base top surface 211 of the supporting base 21 and encapsulating the semiconductor chip 41 and the wires 42. The framing portion 101 may be free of the encapsulant 5. The encapsulant 5 may be made from a light-transmitting encapsulating material selected from silicon or epoxy resin, etc., and may include a fluorescent material. The encapsulating material is well known to those skilled in the art and is not provided herein for the sake of brevity.

With the affinity between the leads 22 and a solder (not shown) disposed in the solder grooves 30, the connection between to the leads 22 and the solder can be visually inspected via the solder grooves 30. In other words, quality of soldering and completeness of electrical connection between solder joints formed by soldering and the external components can be inspected visually. Specifically, the leads 22 having the lead-bottom surfaces 222 are exposed from the solder grooves 30 for use in subsequent electro-plating process. In the abovementioned embodiments, the thickness of each of the leads 22 is smaller than a depth of the respective one of the solder grooves 30 measured from the molding-layer bottom surface 312 to the lead bottom surface 222, and the leads 22 are not exposed from the joint portions (C) of the molding layer 31. When the semiconductor device packages 2 are singularized, the wear of the cutting member and the burr formed on the edge of the metallic leadframe unit 20 caused by dicing along the scribe line extending along the dicing regions (X) is reduced.

It is noted that each of the methods of making the first and second embodiments may further include film-plating process after the formation of the molding layer 31. For each of the singularized semiconductor device packages 2, at least one electro-plating layer may be formed on the metallic leadframe unit 20. The electro-plating layer may be made from a metallic material including metal or alloy. To be specific, the metallic material for making the electro-plating layer may be selected from the group consisting of nickel, palladium, silver, gold, and alloys thereof. The electro-plating layer may be a single layer or a multi-layered structure. With the electro-plating layer, for each of the semiconductor device packages 2, adhesion between the metallic leadframe unit 22 and the wires 42 and between metallic leadframe unit 22 and the external components can be enhanced after soldering. The reliability of semiconductor device package 2 is raised accordingly.

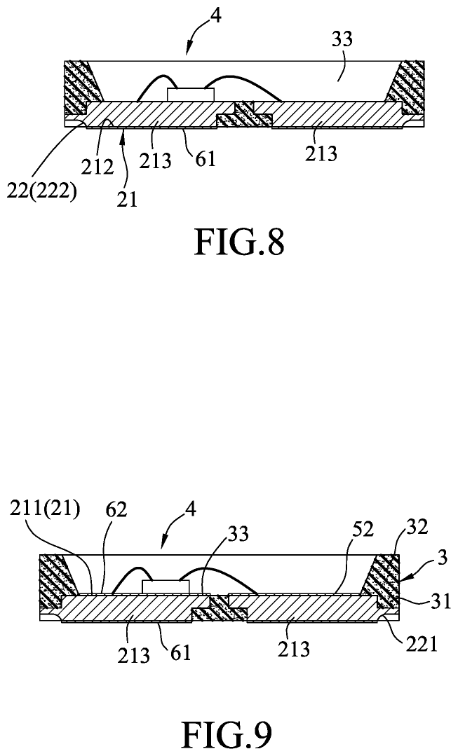

Referring to FIG. 8, in one form, the first embodiment of the semiconductor device package 2 further includes a bottom electro-plating layer 61 that is disposed on the supporting-base bottom surface 212 of the supporting base 21 of the metallic leadframe unit 20. The bottom electro-plating layer 61 is made from a material different from that of the metallic leadframe unit 20.

Referring to FIG. 9, the first embodiment of the semiconductor device package 2 may further include a top electro-plating layer 62 that is disposed on a region of the supporting-base top surface 211 of the supporting base 21 where the supporting-base top surface 211 is uncovered by the upper molding layer 32. The top electro-plating layer 62 is made from a material different from that of the metallic leadframe unit 20.

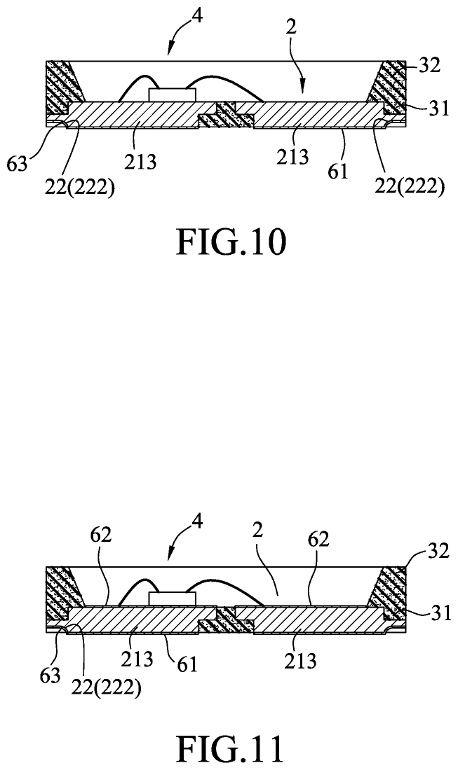

Referring to FIG. 10, the first embodiment of the semiconductor device package 2 may further include a groove electro-plating layer 63 that is disposed on the lead bottom surfaces 221 of the leads 22 of said metallic leadframe unit 20 as shown in FIG. 8 and that is made from a material different from that of the metallic leadframe unit 20.

Alternatively, referring to FIG. 11, the groove electro-plating layer 63 may be disposed on the lead bottom surfaces 221 of the leads 22 of the metallic leadframe unit 20 as shown in FIG. 9.

By way of the inclusion of the top, bottom and groove electro-plating layers 61, 62, 63, a quality and the reliability of the connection between the metallic leadframe unit 20 and the wires 42 and between the metallic leadframe unit 20 and the encapsulant can be improved. In addition, compared with a conventional method of making a leadframe unit including multiple electro-plating steps, the formation of the top, bottom and groove electro-plating layers 61, 62, 63 of the disclosure can be completed in a single electro-plating process.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

1. A semiconductor device package, comprising:
a metallic leadframe unit including a supporting base and a plurality of spaced-apart leads each extending from said supporting base, said supporting base having a supporting-base top surface and a supporting-base bottom surface opposite to said supporting-base top surface, each of said leads having a lead bottom surface non-coplanar with said supporting-base bottom surface;
a molding layer surrounding said supporting base and said leads of said metallic leadframe unit, said molding layer having a molding-layer top surface, a molding-layer bottom surface opposite to said molding-layer top surface and a molding-layer side surface connected between said molding-layer top surface and said molding-layer bottom surface, said supporting-base top surface being exposed from and coplanar with said molding-layer top surface, said supporting-base bottom surface being exposed from and coplanar with said molding-layer bottom surface;
a plurality of solder grooves each indented from said molding-layer bottom surface and located under a respective one of said leads such that said lead bottom surfaces of said leads are uncovered by said molding layer, each of said solder grooves having a first end meeting said supporting base and a second end opposite to said first end and opening at said molding-layer side surface, each of said solder grooves being cooperatively defined by said molding layer and the respective one of said leads; and
a semiconductor device disposed on said supporting-base top surface of said supporting base of said metallic leadframe unit,
wherein said molding-layer side surface of said molding layer has a plurality of surface sections connected with each other, any two adjacent ones of said surface sections defining a joint portion therebetween, each of said leads being exposed from a corresponding one of said surface sections of said molding-layer side surface; and
wherein said metallic leadframe unit is unexposed from said joint portions of said molding-layer side surface.

2. The semiconductor device package of claim 1, wherein said supporting base of said metallic leadframe unit includes at least two contact electrodes that are spaced apart from each other, each of said leads extending from a corresponding one of said contact electrodes, said contact electrodes respectively having top ends constituting said supporting-base top surface and bottom ends constituting said supporting-base bottom surface, said molding layer being filled in a gap between said contact electrodes and surrounding said contact electrodes.

3. The semiconductor device package of claim 2, further comprising an upper molding layer disposed on said supporting-base top surface and partially covering said top end of each of said contact electrodes to form a mounting area that is exposed from said upper molding layer, said semiconductor device being disposed in said mounting area.

4. The semiconductor device package of claim 3, wherein said semiconductor device is a light-emitting device, and said upper molding layer is light reflective.

5. The semiconductor device package of claim 2, further comprising an encapsulant directly disposed on said molding-layer top surface of said molding layer and said supporting-base top surface of said supporting base and encapsulating said semiconductor device.

6. The semiconductor device package of claim 1, wherein said metallic leadframe unit is made from a metallic material selected from the group consisting of copper, a copper-based alloy, an iron-nickel alloy, and combinations thereof.

7. The semiconductor device package of claim 3, further comprising a bottom electro-plating layer that is disposed on said supporting-base bottom surfaces of said supporting base of said metallic leadframe unit, said bottom electro-plating layer being made from a material different from that of said metallic leadframe unit.

8. The semiconductor device package of claim 7, further comprising a top electro-plating layer that is disposed on a region of said supporting-base top surface of said supporting base where said supporting-base top surface is uncovered by said upper molding layer, said top electro-plating layer being made from a material different from that of said metallic leadframe unit.

9. The semiconductor device package of claim 8, further comprising a groove electro-plating layer that is disposed on said lead bottom surface of said leads of said metallic leadframe unit and that is made from a material different from that of said metallic leadframe unit.

10. The semiconductor device package of claim 1, wherein said molding layer is directly molded over said metallic leadframe unit.
